(19) United States
(12) Patent Application Publication
(10) Pub. No.: US 2006/0255971 A1
(43) Pub. Date: Nov. 16, 2006

(54) Keypad for enhancing input resolution and method for enhancing input resolution using the same

(75) Inventor: Eal Goo Kim, Seoul (KR)

Correspondence Address: SUGHRUE MION, PLLC, 2100 PENNSYLVANIA AVENUE, N.W., SUITE 800, WASHINGTON, DC, 20037, US

(73) Assignees: Eal Goo Kim; MCQUINT ELECTRONICS INC.

(21) Appl. No.: 11/315,210

(22) Filed: Dec. 23, 2005

(30) Foreign Application Priority Data
May 11, 2005 (KR) 10-2005-0039447
May 24, 2005 (KR) 10-2005-0043645
May 30, 2005 (KR) 10-2005-0045487
Jun. 17, 2005 (KR) 10-2005-0052304
Aug. 26, 2005 (KR) 10-2005-0078902

(51) Int. Cl. H03K 17/94; H03M 11/00

(52) U.S. Cl. 341/34; 341/22

(57) ABSTRACT

The present invention relates to a keypad with built-in touch sensors and touch signal processing units, and a method for increasing the input resolution of the keypad by evaluating a signal of the contact strength and eliminating a redundant signal, which enables a selection of a user's choice in an one-touch one-entry text input mode. The key pad in accordance with the present invention allows for a user to select the desired letter in a single step from a three by four keypad in a one-touch one-entry mode with a high speed and accuracy.

### RELATED APPLICATIONS

The present disclosure relates to subject matter contained in priority Korean Application Nos. 10-2005-0039447 filed on 11 May 2005, 10-2005-0043645 filed on 24 May 2005, 10-2005-0045487 filed on 30 May 2005, 10-2005-0052304 filed on 17 Jun. 2005 and 10-2005-0078902 filed 26 Aug. 2005, which are herein expressly incorporated by reference in its entirety.

### BACKGROUND OF THE INVENTION

1. Field of the Invention

The present invention relates to a keypad for enhancing the input resolution of the keypad, and more particularly to a keypad with built-in touch sensors and touch signal processing units, and a method for increasing the input resolution of the keypad by evaluating a signal of the contact strength and eliminating a redundant signal, which enables a selection of a user's choice in an one-touch one-entry text input mode.

2. Description of the Related Art

It has become clear that an emphasis of a cellular phone today is shifting from initially intended mobile communications as a handset to a multi-functional intelligent entertainment and internet functions. A statistics reveals that in some countries a proportion using a handset as a message sending device has already exceeded that using it as a voice transmitting and receiving one.

This kind of shift in emphasis is also true for television sets which were originally invented for receiving audio and video signals as the transition speed of a system digitalization accelerates.

A common observation with this trend, however, is that a keypad usually found in a cellular phone or a remote controller, which represents a human-machine input interface, has hardly changed from its original form of a number inputting device.

To keep up with changing environments of the so-called handset era of mobile communications and the TV-centric home entertainment systems, it is of absolute necessity for the keypad of the cellular phone or the remote controller to be equipped with a user-friendly text mode character input.

The irony with the input devices, however, is that the various attempts to introduce a shape of the keypad other than a “standard” arrangement of a 3×4 key form have failed to find a wide acceptance from a majority of users. At least for the time being, it seems safe to conclude that users want a truly user-friendly input device and the shape of the keypad should not depart from a-conventional 12 push button system.

FIG. 1a illustrates a cross-sectional view of a typical keypad with metal dome switches that represent a most widely used mechanical contact based switch matrix.

As shown in FIG. 1a, the keypad consists of various key buttons 110a through 110d, a cover 120 with protruded actuators, a metal dome switch matrix 130, a motherboard 140 for an internal circuit, and a flexible band wire connector 150, wherein the key buttons are installed on a surface of a case material 160.

This kind of configuration employing the switch matrix is a result of two technical aspects. The first one is to reduce the number of connection wires of the flexible band wire connector 150 connected to the motherboard 140 for the internal circuit, instead of assigning independent connecting wires from each push button. The switch matrix also increases flexibility in assigning functions to each key contact, which is an important viewpoint in upgrading the phones from one generation to another.

The second aspect, more important of the two, is to prevent the internal circuit on the motherboard 140 from being affected by environmental fluctuations. As is well known, a human body is a receiver and transmitter of a noise from a ubiquitous 60 Hz hum, and an electrostatic discharging process through a finger contact may even destroy electronic components of a circuit. The switch matrix converts the signal of a finger contact into a mechanical contact signal of the two connecting wires through the metal dome switch 130, eliminating the possibility of a finger influencing the internal circuit directly.

FIG. 1b shows a disposition of conducting wires in the switch matrix as a representative case of the most commonly employed mechanical contact based switch matrix used in the keypad. An operation principle is as follows: when a key on a number keypad or one of the navigation keys is pressed, a dome-shaped membrane underneath the actuator, which protrudes over the opposite side of a key, is bent to form an electrical connection at a cross point where the conducting wires are running in horizontal and vertical directions, and register the user's input.

Although not shown in a separate figure, this operation principle also applies for a rubber button type switch matrix or a membrane switch matrix whose operation principle is based on a creation of an electrical path between the conducting wires in a matrix form.

The operation of the mechanical contact based switch matrix is described with reference to FIG. 1b in detail. When a physical pressure is exercised at a point on a surface of an input device where conducting lines in x and y direction are crossing each other, an electrical contact is created at one of intersection points 135a through 1351 of the wires. For instance, if a key button is pushed down at an intersection point 135c of a Line 1 and a Line C, the metal dome of the switch is pressed to touch the Line 1 and Line C simultaneously, and the Line C will respond to a signal applied to the Line 1, or vice versa, as a result of the electrical signal path created through the mechanical contact.

This kind of mechanical contact based switch matrix is widely used in mobile electronics equipments such as mobile handsets or remote controllers for TV sets, where the numbers are usually positioned first and several additional functions are added.

For a purpose of a cost reduction, or aesthetical reasons, a form of the keys may deviate from the conventional button type.

FIG. 1c shows a shape of such a keypad wherein keys are integrated into a case material thereof like leaves hanging on a tree, such that a differentiation of a key region from a surrounding separation region in classical sense does not apply.

FIG. 1d is a cross-sectional diagram of that configuration.

As illustrated, a keyboard comprises a projection cover 120 on which actuators 121a through 121d protrude over a rubber plate, a mechanical contact based switch matrix 130 having metal dome switches 131a through 131d thereon, a motherboard 140 for an internal circuit, and a flexible band wire connector 150, a coated film for coloring 170 as well as a layer of transparent film 180 that covers the coloring film. The projection cover 120 consists of a rubber material that allows the metal dome switches 130 to be pressed easily. Considering forms of these modified keys that correspond to numbers and characters, as well as other possible types of keys, the term “key” from hereinafter will be defined as a “a position of inputting a character,” i.e., the place where a push action for a purpose of selecting a desired number or character occurs.

The most commonly used method of a keypad using character input as illustrated in FIG. 1a or 1c is to assign several characters to one key and select the desired character by pressing the key multiple times (multi-tapping). Besides a general fact that an actual input speed is significantly delayed as one key must be pressed multiple times in order to get a desired character, there is a serious drawback occurring by the use of this kind of keypad: the considerable slowdown of speed due to the forced waiting time after selecting each character when a desired word is disposed in the same key (for instance, when trying to input the word “cab” when one key is assigned to three letters “abc”). Hence the current input method may hardly be applied even at an elementary level of a short message service (SMS), let alone for a case for full-scale word processing.

The most natural approach to satisfying needs of a mobile internet era would be to increase the number of keys, for example 5×7 by some companies or other number of keys by others, so that each key will have one letter assigned to it for convenient input process.

However, such an increase in the speed of character input through addition of extra keys entails getting used to each manufacturing company's keypad arrangement for each new phone purchased, not to mention requiring higher level of concentration to maneuver through multitude of keys in a crowded and limited space.

Nevertheless, it is an undeniable fact that what users ultimately want is an already familiar qwerty-type of keypad arrangement of a typewriter, and consequently, there have been companies that have attempted to come up with a usable qwerty-type keypad.

Some companies have launched a mobile communications handset that contains a straightforward implementation of 40 keys on the input area directly, while some others have introduced a mobile communications handset that accommodates separate interior character input keys. These approaches are made to enhance an input resolution, which is a concept describing a density of input characters on a given area of an input pad.

With an intention of reducing an inconvenience of using many small keys in a limited space, some companies have employed a help of software to select a meaningful combination of buttons pressed from a keypad wherein only two characters are assigned to each key as a compromise of reducing the number of keys that need to be positioned in a constrained space and alleviating an inconvenience of multi-tapping.

Some companies have also tried to take a full advantage of the potential of software support even by using a standard layout of a keypad which helps the user by extracting a word from a sequence combination of keys pressed. The representative case is a T9 method, in which meaningful sequences are extracted from applications of 3×3 keypads.

Regardless of what approach is taken to provide the text input function on a cellular phone, given that the user would still need to be familiar with the use of the 3×4 key arrangement, the method for text input should not depart far from the conventional way. The natural conclusion from this observation is simple and clear: A text input device should be such that the user may select the desired letter in a single step from a 3×4 keypad, that is to say, in the one-touch one-entry mode. A logical next step in response to this requirement would be to use a key with tilt sensors instead of a simple form of a key button. Unfortunately, a realization of such kind of key is challenging due to the fact that it would require a high degree of mechanical precision during the fabrication process as well as in the actual operation, which some of the times may be harsh environments. Such challenges lead to the problem of cost and reliability.

### SUMMARY OF THE INVENTION

It is an object of the present invention to provide a keypad with built-in touch sensors and touch signal processing units, and a method for increasing the input resolution of the keypad by evaluating a signal of the contact strength and eliminating a redundant signal, which enables a selection of a user's choice in an one-touch one-entry text input mode.

In order to achieve the above-described object of the present invention, there is provided a keypad for enhancing an input resolution, the key pad comprising: a plurality of keys, each of the keys corresponding to one or more assigned characters, wherein the plurality of the keys are constructed to receive an input of a desired character from the assigned characters; one or more touch sensors disposed to correspond to the plurality of the keys and perceive a touch status of a user; a touch signal processing unit for receiving a signal and evaluating a corresponding contact strength in an event that a contact is made at the touch sensors; and an input character selection unit for choosing a character of the user's choice from a plurality of characters by analyzing an electrical signal generated by the touch signal processing unit.

In order to achieve the above-described object of the present invention, there is also provided a method for enhancing an input resolution using a keypad including a plurality of keys and one or more touch sensors disposed to each of the keys in order to sense a contact status of a user, the method comprising steps of: assigning one or more characters to each of the keys on the keypad; measuring a contact strength signal using the touch sensors; and selecting a character intended by the user by analyzing the contact status.

### BRIEF DESCRIPTION OF THE DRAWINGS

FIG. 1a is a cross-sectional view illustrating a keypad used in a conventional mobile communication handset.

FIG. 1b is a drawing illustrating a principle arrangement of conducting lines in a switch matrix used in a conventional mobile communication handset.

FIG. 1c is a top view illustrating another keypad used in a conventional mobile communication handset.

FIG. 1d is a cross-sectional view illustrating another keypad used in a conventional mobile communication handset.

FIG. 2a is a block-diagram illustrating an input resolution enhancing keypad in accordance with a first preferred embodiment of the present invention.

FIG. 2b is a block-diagram illustrating an input resolution enhancing keypad in accordance with a second preferred embodiment of the present invention.

FIGS. 3a through 3c show the arrangement of touch sensors on a keypad in accordance with the present invention.

FIGS. 4a through 4g illustrate another configuration and location of touch sensors for a keypad in accordance with the present invention.

FIG. 5a through 5c illustrate a disposition of sensing lines for a column of keys on a position of keys which belong to an adjacent column of a keypad.

FIG. 6a through 6c illustrate a configuration of a touch signal processing unit on a keypad in accordance with the present invention.

FIG. 7 is a block diagram of a touch signal processor according to an embodiment of the present invention.

FIG. 8 illustrates an example of an arrangement of sensing lines on a keypad.

FIG. 9a demonstrates an example of a keypad which is constructed according to the first and second preferred embodiments of the present invention.

FIG. 9b illustrates an example of a keypad constructed according to the first and second preferred embodiments of the present invention.

FIG. 9c extends the one-touch one-entry mode application in a 3×4 layout to Japanese characters while maintaining that the construction of the keypad still agrees with the first and second preferred embodiments of the present invention.

### DETAILED DESCRIPTION OF THE INVENTION

Embodiments in accordance with the present invention will now be described in detail with reference to the accompanied drawings.

The present invention will now be described in detail with reference to the accompanied drawings.

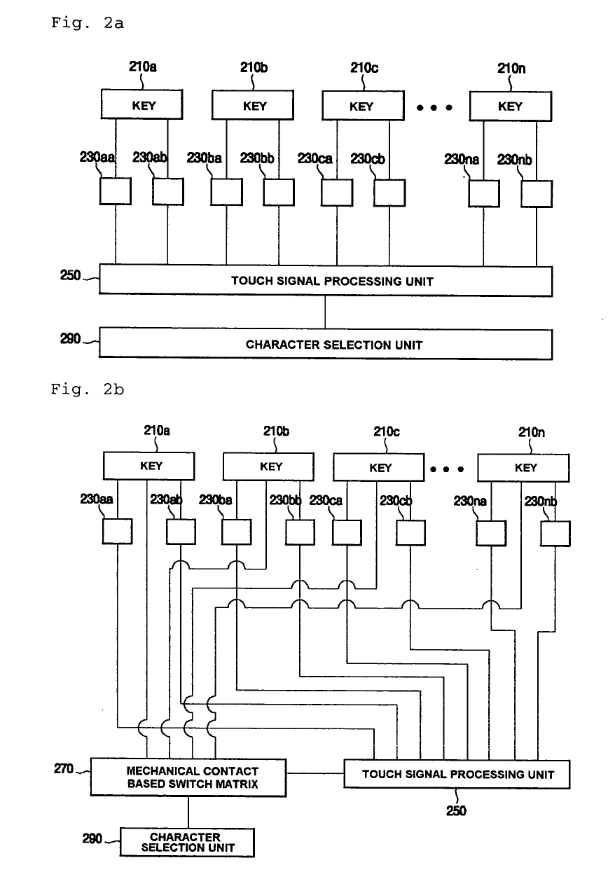

FIG. 2a is a block-diagram of a keypad for enhancing an input resolution in accordance with a first preferred embodiment of the present invention.

As shown, the keypad comprises keys 210a through 210n, touch sensors 230aa through 230nb, a touch signal processing unit 250, and a character selection unit 290.

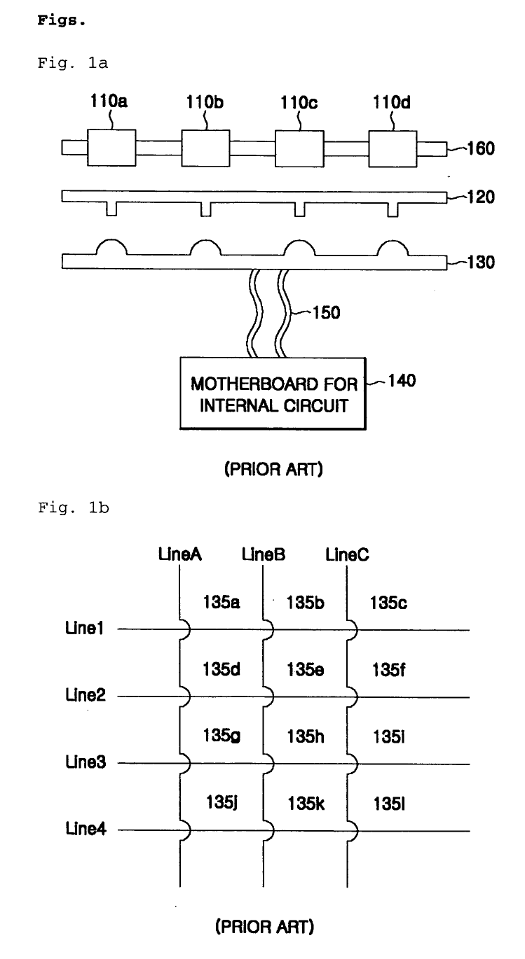

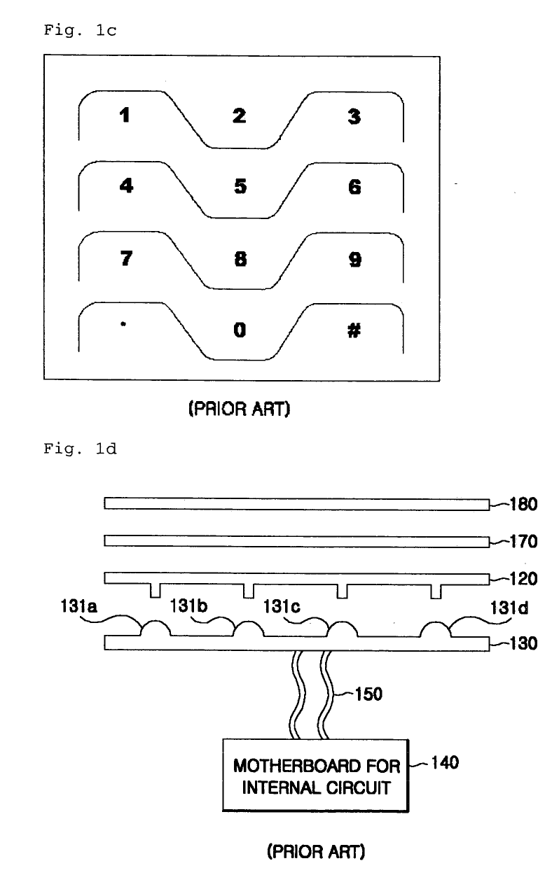

The keys 210a through 210n on the keypad may be a touch button type shown in FIG. 1a or a leaf-key type shown in FIG. 1c, wherein one or more characters for the keys are drawn on a surface of the handset to be chosen and inputted.

The keys 210a through 210n may be arranged similar to the conventional 3×4 layout or a different format.

Furthermore, each of the keys may have more than one character assigned thereto.

For instance, letters Q and W may be assigned to the key 210a in FIG. 2a, or even Q, W; and E, to enable inputting a character of choice.

The number of the keys 210a through 210n may vary depending on a type of the keypad layout as in the conventional 3×4 layout or a different one according to a design of the keypad.

The touch sensors 230aa through 230na for one or more numbers are assigned to each of the keys 210a through 210n.

For example, the sensors may be configured as in FIG. 2a so that letters Q and W are assigned to the key 210a, and touch sensors 230aa and 230ab correspond to the key 210a in FIG. 2a. Letter Q will be selected when the touch sensor 230aa is in contact with a finger, and letter W will be selected when the touch sensor 230ab is in contact with the finger.

Although the touch sensors 230aa through 230nb are shown to be two for each of the keys 210a through 210n as an example, the number of touch sensors for a key may vary according to the number of characters assigned to each key.

The touch sensors may be disposed to a left and a right side of each of the keys 210a through 210n, or to the left, right, upper, and lower part, or even to the upper left, upper middle, upper right, lower left, lower middle, and lower right area of each of the keys.

The touch signal processing unit 250 senses the degree of contact strength at the contact to the touch sensors 230aa through 230nb, evaluates the signals from the touch sensors, and generates the signals for the character selection unit.

The character selection unit 290 receives the generated signal from the touch signal processing unit 250 and selects the character of the user's choice.

That is, the keypad in accordance with the first preferred embodiment of the present invention, which was explained with the reference to FIG. 2a, is constructed in a way that the touch sensors 230aa through 230nb are assigned to the keys 120a through 120n to enable the appropriate selection of the user's intended choice of character based on the signals generated by the touch signal processing unit 250.

The character selection unit 290 may also engage in functions other than the character selection. For instance, since the combination of a key and the touch sensors adjacent thereto may be detected from which side the key is contacted, it may perform the cursor moving function, which is usually carried out by the navigation key in the conventional cellular phone.

The keypad in accordance with the first preferred embodiment of the present invention may be applied to a conventional keypad that uses the mechanical contact based switch matrix.

That is, the character selection unit 290 may receive and analyze signals from both the touch signal processing unit 250 and the mechanical contact based dome switch as the user presses the keys 210a through 210n to transmit the selection signal for the character of his or her choice.

The difficulty here is that, as explained in the description of the related art, the internal circuitry may experience harmful effects from the noise and electrostatic discharge caused by a finger contact.

A signal conversion process is therefore desirable as it merges the signal from the touch signal processing unit 250 to one generated from the mechanical contact based switch matrix.

FIG. 2b is a block diagram of a keypad that enhances the input resolution in accordance with the first preferred embodiment of the present invention. As shown, the keypad comprises the keys 210a through 210n, the touch sensors 230aa through 230nb, the touch signal processing unit 250, and the character selection unit 290.

The keys 210a through 210n are constructed to deliver a touch signal in response to the mechanical contact based switch matrix. Furthermore, one or more characters are assigned to each of the keys as in FIG. 2a.

For the touch sensors 230aa through 230nb, an assignment of the characters to each of the keys is the same as the case shown in FIG. 2a.

The touch signal processing unit 250 receives an electrical signal with respect to the degree of contact strength when the touch sensors 230aa through 230nb experience a finger contact.

The mechanical contact based switch matrix 270 comprises multiple intersection points of conducting lines running in two different directions. A portion of the intersection points corresponds to the keys 210a through 210n and forms an electrical path between the conducting lines when one of the corresponding keys 210a through 210n is pressed by a user.

A remaining portion of the intersection points that are occupied by the corresponding keys are assigned to output nodes of the touch signal processing unit 250, which includes a signal converter. The signal converter provides an electrical connection between the conducting lines that meet at the intersection points when the finger contact prompts the touch sensor.

The signal converter, which is not shown explicitly in figure, is connected to the touch sensors and comprises a contact status detecting circuit and transmission gates for the portion of the intersection points not corresponding to the keys 210a through 210n.

The character selection unit 290 is subject to the electrical signal from the mechanical contact based switch matrix 270 and selects the character of the user's choice from the multiple characters assigned to each key 210a through 210n. The mechanical contact based switch matrix 270 delivers signals generated by a press of a key as well as signals that are converted from the touch signals based on the contact status of the touch sensors 230aa through 230nb.

In the following, the configuration of the keypad in accordance with the first and second preferred embodiments of the present invention will be explained in detail.

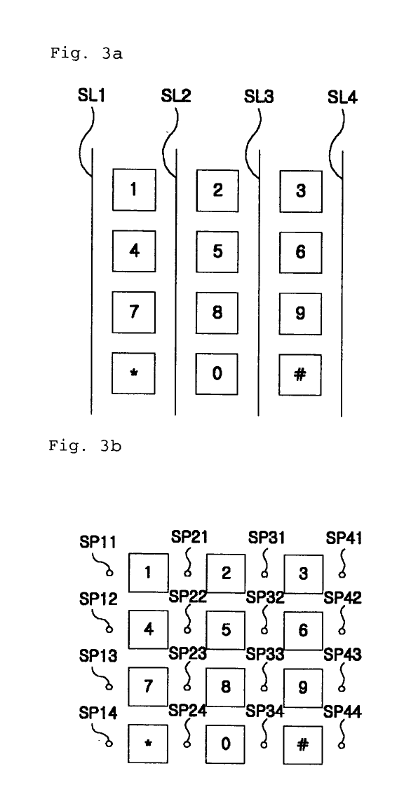

FIGS. 3a through 3c suggest different positions at which the touch sensors may be disposed. Each touch sensor is arranged for a 3×4 keypad in FIGS. 3a through 3c.

The touch sensors may have a form of sensing lines SL1 through SL4 on a case material as shown in FIG. 3a, or of sensing points SP11 through SP44 on the case material as shown in FIG. 3b, or of sensing points S11 through S14 and S41 through S44 at some points on the surface of the case material and others disposed at positions S21 through S24, SP21′ through S24′, SP31 through SP34, and SP31′ through SP34′ where the keys are disposed as shown in FIG. 3c.

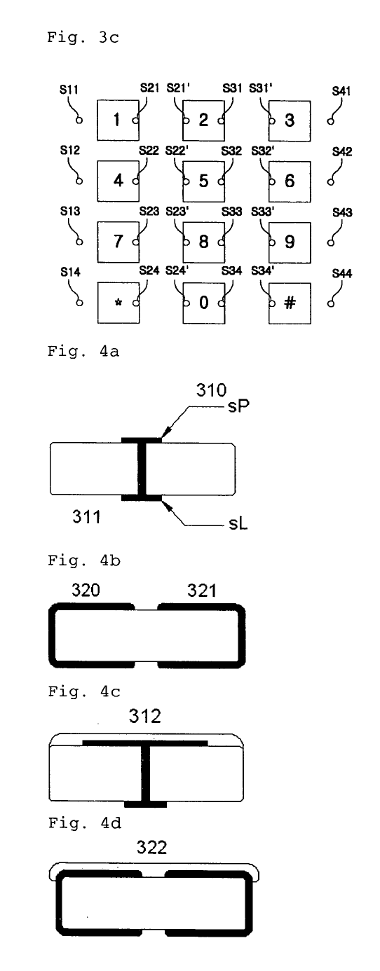

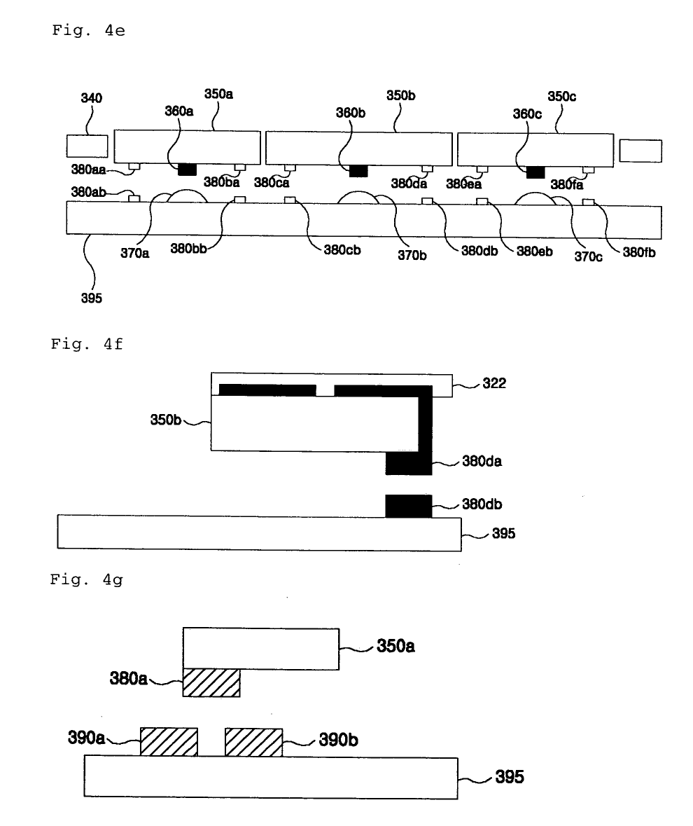

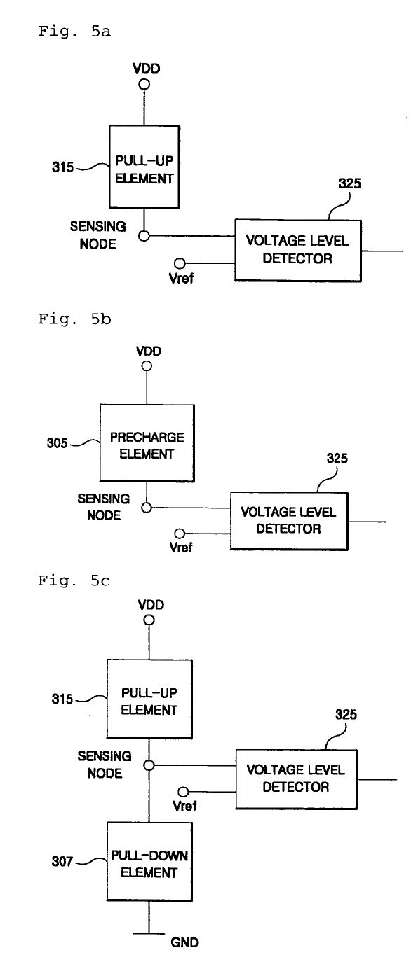

Furthermore, the touch sensors may take on various forms as shown in FIGS. 4a through 4g. Some possible forms include having an exposed sensing electrode on a surface 310 which is connected to an opposite side of a surface 311 through a hole as shown in FIG. 4a, or a surface portion is connected to an inner portion by a coated conducting layer 320, wherein the sensing electrode may have a form of split electrodes 320 through 321 as suggested in FIG. 4b. Furthermore, the sensing electrodes may be covered by insulating layers 312 and 322 as shown in FIGS. 4c and 4d. These sensing electrodes with coated layer of insulator are for evaluation of the contact strength on a basis of capacitance measurements, while those with the exposed conducting layer on a basis of contact resistance measurements.

It should be noted that a touch sensor is not required to have its sensing electrodes directly exposed to a finger contact. FIG. 4e illustrates another example of the touch sensor. Here, upper electrodes 380aa through 380fa of the touch sensor are disposed at a bottom of keys 350a through 350c, while lower electrodes 380ab through 390fb are disposed at a surface of a substrate plate 395 where the mechanical contact based switches 370a through 370c are disposed.

Besides, it is clear that the touch sensor for the keypad enhancing the input resolution in accordance with the first and second preferred embodiments of the present invention may take any combination of the sensing electrodes shown in FIGS. 4a through 4e or any other forms of electrodes not explicitly shown in the figures.

FIG. 4f exemplifies how various types of the sensing electrodes may be combined to form the touch sensor. The touch sensor in this example comprises a lower electrode 380db at a bottom of the switch matrix plate 370, while an upper electrode 380da is connected to the surface of the key 350b through a conducting layer which is covered by an insulating layer 322.

FIG. 4g illustrates an arrangement of the touch sensors for a keypad in accordance with the present invention, wherein the upper electrode 380a is disposed at a lower left of the key 350a and the bottom electrodes 390a and 390b are disposed on the substrate plate 395 so as to correspond to the upper electrode 380a.

When, for example, a user exerts a pressure on the left side of a key 350a so that the upper electrode 380a touches both of the bottom electrodes 390a and 390b, an electrical path is provided between the bottom electrodes 390a and 390b by the upper electrode 380a, wherein the former correspond to the interconnection lines of the switch matrix and the latter to the metal dome.

The most straightforward implementation method of the sensing electrodes for a conventional key will be described with reference to FIG. 4e, wherein the sensing electrodes are disposed underneath the keys.

The addition of these touch sensors on both side of the key in accordance with the present invention extends the function of a conventional switch matrix of one-way switches to that of a hybrid switch matrix of three-way switches, whose operation mode will be explained with reference to FIGS. 4e and 1c.

The conventional metal dome switch takes a role of a “main switch” for providing the information regarding which key is pressed, while the contact switches at the side-wings of the key takes a role of an “auxiliary switch” for providing the information regarding which side of the key is pressed. The only difference is that the bottom electrodes at the metal dome switch are in a form of concentric circles, while here they are in a form of sensing lines. However, from the viewpoint of electrical properties of a switch matrix, the operation of a metal dome switch and the contact switch of the conducting layers at the side of a key is identical, since both of them provides the same function of providing an electrical path between the horizontal lines Line1 through Line4 and vertical lines LineA through LineD at intersection points 131a through 1311.

Although the principle of the operational is simple, this method suffers from a drawback in the sense of high level of mechanical precision during the fabrication process and during the operation by a user. For that purpose of ensuring a sufficient margin in the sense of long-term reliability, an introduction of electrical sensing mechanism is of prime importance.

For that purpose the keypad for enhancing input resolution in accordance with the present invention is equipped with touch sensors which are composed either of a conducting surfaces 310, 320 and 321 or a conducting material covered with an insulating layers 312 and 322 as shown in FIGS. 4a through 4g.

It is to be noted here that whether a conducting layer is exposed to a finger contact or not does not make a significant difference in sensing mechanism, since the finger itself is a combination of a resistance and a capacitance in electrical sense.

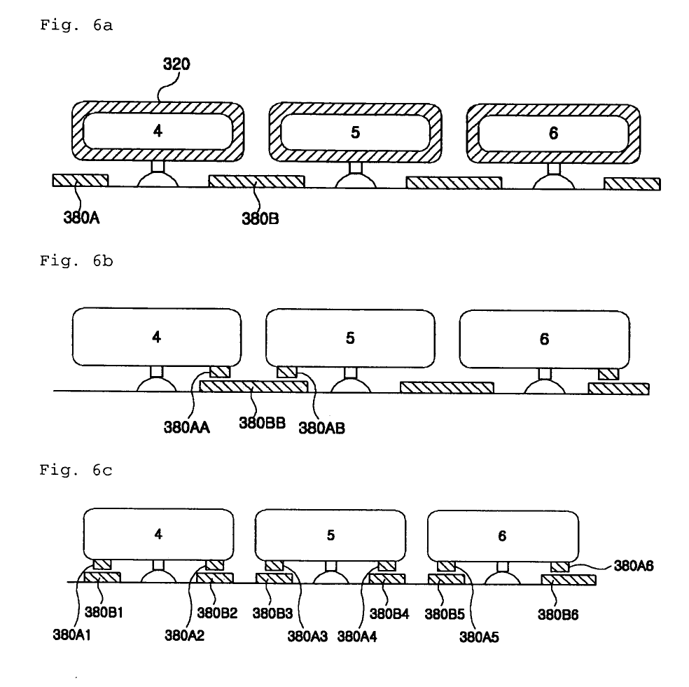

FIG. 5a through 5c illustrate an example of a touch sensor of a keypad in accordance with the present invention. Using this kind of sensing mechanism, the touch sensing unit may be constructed to measure the degree of a touch strength of a finger to the sensing node, which is a terminology to designate the sensing point in the sense of an electrical circuit.

A method of FIG. 5a simply employs a pull-up resistor as a pull-up element 315. When a finger touched the sensing node, the pull-up resistance and a resistance of the finger forms a voltage divider, and then a magnitude of a generated voltage is compared to that a Vref to determined by a voltage level detector 325 whether a contact has been established. The magnitude of Vref is varied appropriately, and a signal may be detected at a level about one half of a supplied voltage without using the Vref when an inverter is used.

However, a 60 Hz hum is applied when the finger is in contact, thereby generating an unclean signal. However, the method is very useful when the finger does not directly touch the sensing node.

In accordance with a method of FIG. 5b, the sensing node is charged during a given time instead of providing a pull-operation continuous for a certain time in order to reduce an effect of a noise.

An operation cycle of touch sensing is divided into two phase: the precharge phase and the evaluation phase. During the precharge phase, the sensing node is brought to a predetermined voltage VDD, by turning on the precharge element 305. At the end of this precharge phase the charge stored at the sensing node is the product of the predetermined voltage VDD and the capacitance Cp, wherein the capacitance Cp comprises of the parasitic capacitance related to the sensing node and finger capacitance if there is a finger contact at the sensing node during the precharge phase. By turning off the precharge element 305 the evaluation phase begins, where the stored charge at the sensing node is redistributed or discharged according to the contact status at the sensing node, which results in a decay of the node voltage as a function of time. By using a property wherein a time characteristic is changed according to the contact strength, the contact strength may be determined by measuring a time period from a beginning of an evaluation phase to a moment at which an output signal of a voltage level detector varies A method of FIG. 5c uses both R and C component contrary to the methods of FIGS. 5a and 5b depend on the R component of the finger. In accordance with the method of FIG. 5c, the voltage of the sensing node is pulled down to the ground level during the pre-discharge time by the pluu-down element 307. During the pull-down time, the pull-up element 315 may be connected or off, which is not an important factor as long as the pull-down function is powerful. A pre-charge process occurs in an equivalent circuit consisting of the finger, R, C and the pull-up element 315 during the evaluation time, wherein the RC curve changes according to the contact strength of the finger. The contact strength may be obtained by measuring a time until the RC curve reaches the Vref.

FIGS. 6a through 6c illustrate examples of the keypad for enhancing input resolution in accordance with the present invention, wherein the surface of a key button of FIG. 6a is covered by a conducting material 320, while the sensing electrode region is confined to the bottom of a key in the structure of FIGS. 6b and 6c.

In accordance with the operation mode of the structure of FIG. 6a, the sensing electrodes 380A and 380B is precharged during a precharge phase and then which side of the key is contacted, i.e. discharged is detected, during the evaluation phase.

In the sense of an equivalent electric circuit, the conducting layer covering the key functions as an interconnection line between the sensing line and the finger touching the key. Thus, according to the position where a finger presses the key the electrode 380A or 380B or both of 380A and 380B will be discharged to deliver a result whether the left side or the right side or the middle of a key is pressed. Since there does not exist an ambiguity in distinguishing whether either the left side or the right side or both sides of a key are touched, only two sensing lines corresponding to the electrodes 380A and 380B are employed in this structure.

There is another way of operation using a keypad of this type. This operation mode exploits the fact that when the keys in a row are not separated by a case material, a finger pressing a side of a key inevitably touches also a key in the neighborhood. To illustrate the operation mode it is assumed that the key 4 in the left side contains the characters A, S, and D, and the key 5 in the middle contains the characters of F, G, and H.

If a user presses the left side of the key 5, the sensing electrodes on the left side of the key 5 will meet each other earlier than those on the right side of the key 4. Then the letter F is selected. If, on the other hand, a user presses the right side of key 4, and the electrodes at the right side of the key 4 will meet earlier than those on the left side of the key 5. Then the letter D will be selected.

For many applications there are only two characters assigned to a key. In that case, it is sufficient to differentiate only two states: the left side or the right side.

FIG. 6b shows another example of a keypad to enhance input resolution in accordance with the present invention. To each of the keys, there is only one sensing electrode 380AA or 380 AB assigned either on the right side or on the left side. Furthermore, in contrast to the structure of FIG. 6a, the distance between the upper electrodes 380AA and 380AB and lower electrodes 380BB is kept large, so that the combination of the actuator and the metal dome in the middle acts as an axis in order to prevent the case that both sides of a key touches the bottom plate at the same time. Therefore, there are only two cases: either a key pressed so that the upper electrodes meet together or there are no electrodes to be met together.

The operation mode is set so that the upper sensing electrodes 380AA and 380AB attached to the key are precharged while the lower sensing electrode 380BB is held at the ground potential. When the side with an electrode beneath it is pressed, the upper electrode 380AA or 380AB discharges, while in the opposite case the sensing electrode retains the precharged potential. Since the lower sensing electrodes needs not to be separated from each other, but may be merged to a singe ground plane, and since all of the lower sensing electrodes may be connected to form a single sensing line, the whole keypad with two characters on each key may be operated with a single sensing line.

The usability of the keypad structure of FIG. 6b may be extended to the cases where three characters are assigned to each of the key.

FIG. 6c illustrates another example of a keypad to enhance input resolution in accordance with the present invention. Here in this structure, the axis of the key in the middle is disposed in the middle of the key 5 as in a conventional keypad, while that of the key in the left side 4 and that of the key in the right side 6 is shifted to the left and right, respectively.

The operation principle of this structure is as follows. When the left side of the key 4 is pressed, the touch sensor 380B1 is activated, and when the right side of it is pressed, both of the touch sensors 380B2 and 380B3 are activated as explained above. When the finger presses the key 4 in the middle, however, only the touch sensor 380B2 is activated because of the slight displacement of the axis to the left. The case with the key 6 follows the same consideration. A pressure on the left side, right side, and the middle of the key activates the touch sensors 380B4 and 380B5, 380B6, and 380B4, respectively. In the case of the key 5, a pressing of the left side, right side activates the touch sensors 380B2 and 380B3, 380B4 and 380B5, respectively, while a pressure in the middle activates either the touch sensor 380B3 or 380B4. Thus for all the keys in a row, the distinction is clear which side of a key is pressed, enhancing the input resolution of a keypad from three at a conventional keypad to nine in accordance with the present invention.

FIG. 7 is a block diagram of a touch signal processing unit 250 according to the practical implementation of the present invention.

With such a composition for contact status evaluation at the sensing points, the touch signal processor may be constructed by measuring the contact resistance or contact capacitance.

An explanation of the touch processing unit 250 connected to the mechanical contact based switch matrix 270, by way of electronic switch array 430, whose representative example is a transmission gate, is as follows.

The contact strength sensors 410a through 410n evaluate the degree of contact strengths at each of the sensing electrodes of the touch sensors 230aa through 230nb by measuring the time the voltage from each of the sensing electrodes reaches a predetermined value.

A touch signal evaluator 420 evaluates the validity of each signal in context to the signal combination obtained from several contact strength sensors. According to the result of the signal evaluation control signals are delivered to an electronic switch array 430 to turn the corresponding switches on, wherein the representative example of an electronic switch is a transmission gate that provides an electrical connection path between nodes A and B when a control signal of “high ” is applied on its control electrode.

The role of the touch signal processing unit 250 for a keypad for enhancing the input resolution of a keypad according to the second practical implementation of the present invention, comprising the contact strength sensors 410a through 410n, the touch signal evaluator 420, and the electronic switch array 430, as a whole, may be represented by the terminology of a signal converter, which maps the touch status signal at the sensing nodes to a connection status of an electronic switch at the intersection points on a switch matrix.

Besides the fundamental function of evaluating the touch signals in the sense of contact strength, the touch signal evaluator 420 performs two additional functions.

First, in order for the signals from the touch sensors not to overload the switch matrix with unnecessary signals which do not deliver an additional information to those provided by others, the redundancies are eliminated by the touch signal evaluator 420. This function is of necessity to minimize the number of the electronic switches 430 which are to be implemented to a part of intersecting points on a mechanical contact based switch matrix.

Furthermore, in respect to the application of the mobile handsets with inherent lack of touch precision, it carries out the function of enhancing the operation margin, which lets the touch signal processing unit 250 to be tolerant of slight deviations of a touch position, that is, to ignore unintentional contacts at unwanted positions and accept the touch signals at wanted positions even they are weak.

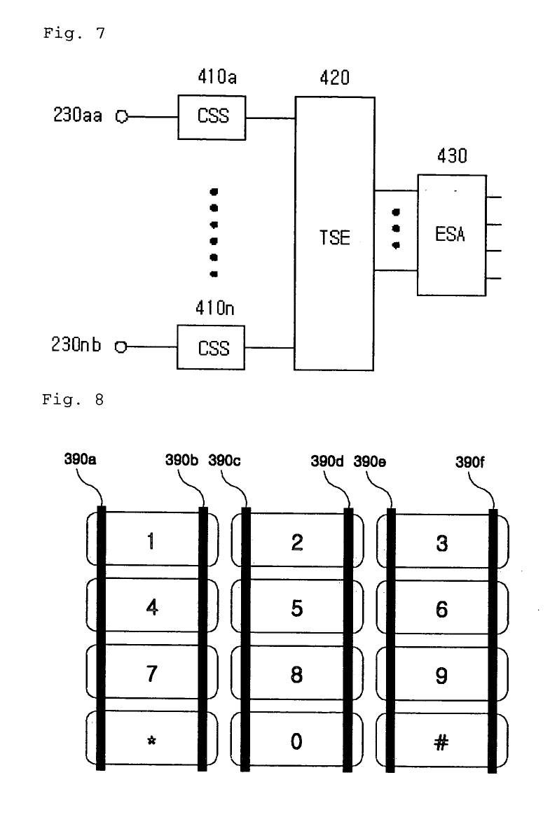

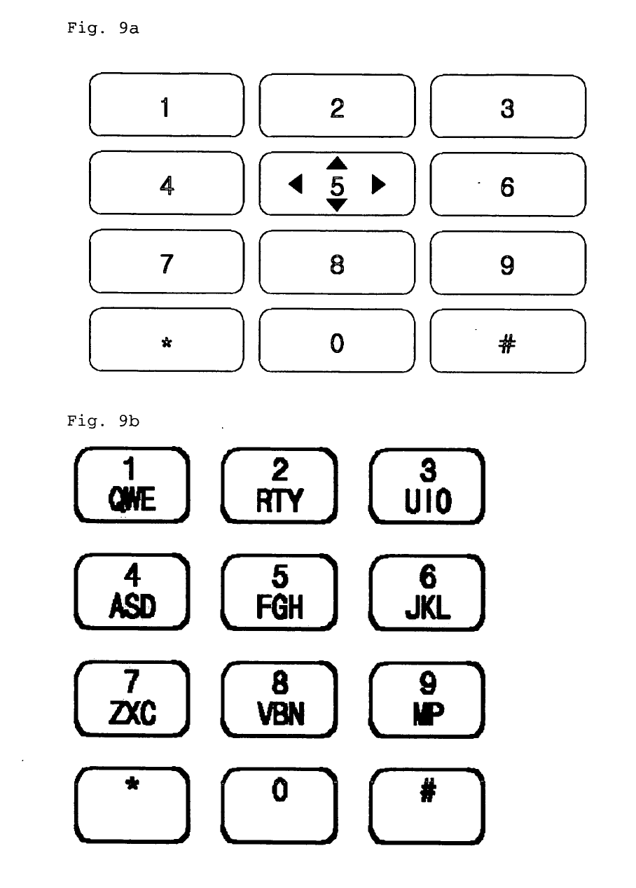

For practical application of a keypad to enhance input resolution it is of prime importance that users do not feel the spaces between the character positions to be disposed too densely. The present invention in respect of this viewpoint will now be described with reference of FIG. 8 which shows an example of an arrangement of sensing lines on a keypad.

As shown, this keypad comprises the keys of 3×4 arrangement and sensing lines 390a through 390f, wherein the sensing electrodes of the touch sensors may take any of the configurations shown in FIGS. 4a through 4g.

Here, a pressure exercised on a key is sensed by the metal dome switch 131a through 131d disposed underneath the corresponding key as in conventional keypad, which carries out the function of “main switch”. The ability of enhancing the input resolution of the keypad stems from the use of the “auxiliary sensor”, which means this auxiliary key is just touched but not pressed.

If, for example, the key 5 is pressed with the “center of pressure” disposed on the left side of the key, the metal dome switch delivers the information that the key 5 is pressed, while the touch signal on the sensing line 390b on the key 4 delivers the direction information of “left”. This consideration is also true for the case where the “center of pressure” is disposed on the right side of the key, with the sensing line 390e on the key 6. When neither the sensing line 390b nor the sensing line 390e is with finger contact, it is interpreted that the key 5 is pressed in the middle.

This kind of implementation of touch sensors on the position of a key in neighborhood increases the “psychological distance ” between the positions to be pressed effectively, since a user receives a necessary tactile sense from the click from the metal dome switch, while the selection of the characters are carried out by the pressing of a point “far from the center of the key”.

Now, the redundancy elimination operation is carried out by the touch signal evaluator 320 as following.

The combination of the touch signals on sensing line 390c and 390d, however, do not provide any independent information as it still remains that they are generated by the finger contact on key 5. The touch signal evaluator 320 may eliminate this kind of signals by conducting the logic operations on the obtained signals, for instance by taking the logic function of XOR. This logic operation is convenient because both sensing points located on a key would deliver the same result of zero.

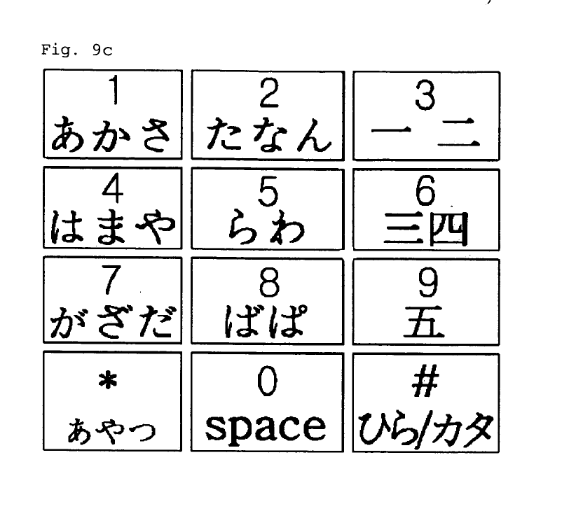

FIG. 9a demonstrates an example of a keypad which is constructed according to the first and second examples of the present invention.

As shown, the function of a navigation key is performed on a key by placing the touch sensors around the key. For example, the navigation key may be implemented at the position of key 5 with the sensing points disposed on keys 2, 4, 6, and 8. During the time the keypad is in cursor moving mode, if key 5 is pressed while at the same time touching the sensing point at key 2, the character selection unit 290 will deliver the signal “up.” Similar outcomes will follow in other cases: if key 5 is pressed while also touching the sensing point at key 8, operation “down” will be carried out, if also key 4, then “left,” and if also key 6, then “right” will result.

Although the example discussed a specific case for key 5 and the sensing points disposed on the surrounding keys, the basic concept may be applied to other keys and sensing points, which may be located on either the surrounding keys, case material surrounding the key, or even the center key itself when the sensing operation of the contact strength sensing unit 3101 through 310n is of sufficient enough degree of precision.

This type of operation may also be applied to character input of the Korean alphabet, where the vowels “ [symbol] ”, “ [symbol] ”, “ [symbol] ”, and “ [symbol] ” resemble the arrows in the directions up, down, left, and right, respectively.

FIG. 9b is an example of a keypad which is constructed according to the first and second examples of the present invention.

As shown, a layout of qwerty-type arrangement of the alphabet is made possible for text input by adopting the following assignments on a 3×4 keypad: letters Q, W, E on key 1; R, T, Y on key 2; U, I, O on key 3; A, S, D on key 4; F, G, H on key 5; J, K, L on key 6; Z, X, C on key 7; V, B, N on key 8; and M, P on key 9. With the relocation of a letter (in this example the P) from upper to lower line, each key now has three letters assigned to it and the user may choose a character in a one-touch one-entry mode.

This basic concept may also be applied to other keypad arrangements than the 3×4 one.

FIG. 9c extends the one-touch one-entry mode application in a 3×4 layout to Japanese characters while maintaining that the construction of the keypad still agrees with the first and second examples of the present invention.

As shown, the assignment of the letters will be as follows to make this kind text input possible: letters [symbol] , [symbol] , [symbol] on key 1; [symbol] , [symbol] , [symbol] on key 2; [symbol] , [symbol] on key 3; [symbol] , [symbol] , [symbol] on key 4; [symbol] , [symbol] on key 5; [symbol] , [symbol] on key 6; [symbol] , [symbol] , [symbol] on key 7; [symbol] , [symbol] on key 8; [symbol] on key 9; and the small letters [symbol] , [symbol] , and z,927 on the key for “*”.

The method of Japanese character input using a keypad such as the one in FIG. 9c is as follows. For example, to input the character ” [symbol] ,” the user may choose the first letter corresponding to character “ [symbol] ,”, i.e., “ [symbol] ,” by pressing the left side of key 7 and letter “ [symbol] ,” which means “five” in Japanese to indicate the letter's fifth place in its group of characters, by pressing key 9.

This kind of operation takes advantage of the fact that Japanese characters may be arranged in such a way that each of the representative letter on keys 1 through 9 and “*” (with an exception of letter “ [symbol] ” and small letter “ [symbol] ”) leads a group of five characters in the order of vowel pronunciation “a”, “i”, “u”, “e”, and “o,” where this order is denoted by the numbers 1 through 5.

Any Japanese character may therefore be mapped on a one-on-one base with a combination consisting of a letter, which represents a group of characters, and an order number, which signifies the letter's place of order in the group. Since it is not likely that there is ambiguity in whether the key was pressed for a representative letter or order number, these two keys required to select a letter may be pressed sequentially or simultaneously.

Thus the use of a keypad as shown in FIG. 9c enables a one-cycle one-entry text input operation.

Although the explanation was given based on the keypad illustrated in FIG. 9c, it should be noted that this one-cycle one-entry text input mode may be applied to other arrangement of characters disposed on the keys according to the basic concept of the present invention.

The present invention also delineates a method of input resolution enhancement for a keypad comprising a plurality of keys, wherein one or more touch sensors are assigned to each corresponding key in order to detect a user's contact to the sensor.

The method begins with the assignment of one or more characters to each of the keys on said keypad. For example, FIG. 9b illustrates a case where the keypad comprises 12 keys and two or three characters are assigned to each of them.

Next, touch signals are obtained from the touch sensors, which will then evaluate the degree of contact strength by way of capacitive measurement or contact resistance measurement method. It is during this phase of operation that touch signals without meaningful information about the contact position is eliminated.

Finally, the character of user's choice is selected among one or more characters assigned to each key based on the analysis of the touch signal status. Furthermore, the operation modes may be organized in such a way that other functions, e.g., that of a navigation key, may be carried out.

The keypads of the present invention are composed of multiple number of keys and one ore more sensors are assigned corresponding to each of the keys in order to discern user's contact to the sensor. For such keypads, methods of input resolution enhancement are similar to those explained in reference to FIGS. 2a through 9c and a detailed explanation is therefore omitted.

While the present invention has been discussed and described with particular reference to the preferred embodiment thereof, it will be understood by those skilled in the art that various changes in form and details may be imposed therein without departing from the spirit and scope of the invention as defined by the appended claims.

1. A keypad for enhancing an input resolution, the key pad comprising:
a plurality of keys, each of the keys corresponding to one or more assigned characters, wherein the plurality of the keys are constructed to receive an input of a desired character from the assigned characters;
one or more touch sensors disposed to correspond to the plurality of the keys and perceive a touch status of a user;
a touch signal processing unit for receiving a signal and evaluating a corresponding contact strength in an event that a contact is made at the touch sensors; and
an input character selection unit for choosing a character of the user's choice from a plurality of characters by analyzing an electrical signal generated by the touch signal processing unit.

2. A keypad for enhancing an input resolution, the key pad comprising:
a plurality of keys, each of the keys corresponding to one or more assigned characters, wherein the plurality of the keys are constructed to receive an input of a desired character from the assigned characters;
one or more touch sensors that are positioned to correspond to the plurality of the keys and perceive a touch status of a user;
a mechanical contact based switch matrix including a plurality of intersection points formed by conducting lines running in two mutually independent directions, wherein a portion of the intersection points is disposed corresponding to the plurality of the keys to convert a mechanical contact signal to an electrical signal when a corresponding key is pressed;
a touch signal processing unit connected to a remaining portion of the intersection points not corresponding to the plurality of the keys, wherein touch signal processing unit includes one or more signal converters for receiving an electrical signal from the touch sensors, and generating an electrical path at the intersection points; and
a character selection unit for analyzing the electrical signal generated by the mechanical contact based switch matrix and for selecting a character selected by a user from a plurality of characters corresponding to each of the keys.

3. The keypad in accordance with claim 2, wherein the signal converter comprises:
contact strength sensors connected to the corresponding touch sensors for detecting a degree of a contact strength;
a touch signal evaluator connected to the contact strength sensors for evaluating a value of the contact strength sensors from each of the touch sensors; and
electronic switches connected to an output of the touch signal evaluator for providing an electrical path between the conducting lines at the corresponding intersection points when a valid control signal is delivered from the touch signal evaluator to the intersection points on the mechanical contact based switch matrix.

4. The keypad for enhancing the input resolution in accordance with one of claims 1 and 2, wherein the plurality of the keys are a button type, each of the keys being separated from a case body.

5. The keypad for enhancing the input resolution in accordance with one of claims 1 and 2, wherein the plurality of the keys are a portion of a case body in a connected form having characters to be selected are marked thereon.

6. The keypad for enhancing the input resolution in accordance with one of claims 1 and 2, wherein the touch sensor perceives an impact of a contact resistance at a sensing node to determine the degree of contact strength at the sensing node.

7. The keypad for enhancing the input resolution in accordance with one of claims 1 and 2, wherein the touch sensor senses an influence of a contact capacitance at a sensing node to detect the degree of contact strength at the sensing node.

8. The keypad for enhancing the input resolution in accordance with one of claims 1 and 2, wherein the touch sensors consists of a conducting material on a surface thereof.

9. The keypad for enhancing the input resolution in accordance with one of claims 1 and 2, wherein the touch sensors consist of an insulating material on a surface thereof.

10. The keypad for enhancing the input resolution in accordance with one of claims 1 and 2, wherein the touch sensors are disposed on a surface of a case body.

11. The keypad for enhancing the input resolution in accordance with one of claims 1 and 2, wherein the touch sensors are disposed on a body of keys.

12. The keypad for enhancing the input resolution in accordance with one of claims 1 and 2, wherein the touch sensors are disposed in an inner space underneath a case body.

13. The keypad for enhancing the input resolution in accordance with one of claims 1 and 2, wherein the touch sensors are disposed in an inner space underneath a key body.

14. The keypad for enhancing the input resolution in accordance with one of claims 1 and 2, wherein the touch sensors are disposed in a space between an inner layers of a keypad structure.

15. The keypad for enhancing the input resolution in accordance with one of claims 1 and 2, wherein the touch sensors are connected together to form sensing lines.

16. The keypad for enhancing the input resolution in accordance with one of claims 1 and 2, wherein sensing electrodes of the touch sensors are divided into two or more individual parts.

17. The keypad for enhancing the input resolution in accordance with one of claims 1 and 2, wherein the touch sensors disposed on a key act as sensing elements with respect to an adjacent key.

18. The keypad for enhancing the input resolution in accordance with one of claims 1 through 3, wherein the touch signal processing unit receives a contact strength signal from the touch sensors and evaluates a strength of the signal to deliver a control signal to electronic switches.

19. The keypad for enhancing the input resolution in accordance with one of claims 1 through 3, wherein the touch signal evaluator receives a touch signal from a contact strength sensors and evaluates a validity of the touch signal in context to the user's intention.

20. The keypad for enhancing the input resolution in accordance with one of claims 1 and 2, wherein the mechanical contact based switches act as a main switch and a touch signal obtained from the touch sensors act as an auxiliary signal to determine a sequence of the user's touch as a function of time.

21. The keypad for enhancing the input resolution in accordance with one of claims 1 through 3, wherein the input character unit carries out predetermined operations other than a text entry function including reception of a combination of signals from the mechanical contact based switches and the touch sensors, and operation as a navigation key.

22. The keypad for enhancing the input resolution in accordance with one of claims 1 through 3, wherein the touch signal processing unit eliminates a redundant signal that does not deliver new and additional information other than those provided by the existing mechanical contact based switch matrix.

23. The keypad for enhancing the input resolution in accordance with one of claims 1 and 2, wherein the plurality of the keys consist of twelve keys or more.

24. The keypad for enhancing the input resolution in accordance with claim 23, wherein one or more alphabet letters are assigned to each of the keys to form a QWERTY type keyboard on the keypad.

25. The keypad for enhancing the input resolution in accordance with claim 23, wherein one of the letters in a top line of the QWERTY type keyboard is moved to a bottom line so that three characters are assigned to each of the keys to form an arrangement of the alphabet according to the QWERTY type keyboard on the keypad.

26. The keypad for enhancing the input resolution in accordance with claim 23, wherein a set of representative Japanese letters and a set of order numbers, signifying the sequence of vowels, are each assigned to different portions of the keypad to enable an one-cycle one-entry text input operation mode for Japanese characters.

27. A method for enhancing an input resolution using a keypad including a plurality of keys and one or more touch sensors disposed to each of the keys in order to sense a contact status of a user, the method comprising steps of:
assigning one or more characters to each of the keys on the keypad;
measuring a contact strength signal using the touch sensors; and
selecting a character intended by the user by analyzing the contact status.

28. The method for enhancing the input resolution in accordance with claim 27, wherein the keypad includes twelve keys arranged in a three by four or a four by three format, and wherein a plurality of alphabets correspond to each of the keys to form a QWERTY type keyboard on the three by four or the four by three.

29. The method for enhancing the input resolution in accordance with claim 27, wherein the keypad includes twelve keys arranged in a three by four or a four by three format, and wherein a plurality of representative Japanese letters or order numbers correspond to each of the keys on the key pad so that an input operation of the Japanese letter is executed in a one-cycle one-entry mode on a twelve-key keypad.

30. The method for enhancing the input resolution in accordance with claim 27, wherein the step of measuring the contact strength signal comprises eliminating a redundant and unnecessary signal.

31. The method for enhancing the input resolution in accordance with claim 27, wherein analyzing the contact status comprises a predetermined function other than character input operation.

32. The keypad for enhancing the input resolution in accordance with claim 24, wherein one of the letters in a top line of the QWERTY type keyboard is moved to a bottom line so that three characters are assigned to each of the keys to form an arrangement of the alphabet according to the QWERTY type keyboard on the keypad.
